(19) United States
(12) Patent Application Publication
(10) Pub. No.: US 2026/0213122 A1
(43) Pub. Date: Jul. 23, 2026

(54) SUBSTRATE INSPECTION APPARATUS AND SUBSTRATE INSPECTION SYSTEM

(71) Applicant: SAMSUNG ELECTRONICS CO., LTD., Suwon-si (KR)

(72) Inventors: Daeyoung Yang, Suwon-si (KR); Kyungjoon Ahn, Suwon-si (KR); Ilsuk Park, Suwon-si (KR); Hyungseop Kim, Suwon-si (KR); Seongchae Choi, Suwon-si (KR)

(73) Assignee: SAMSUNG ELECTRONICS CO., LTD., Suwon-si (KR)

(21) Appl. No.: 19/439,670

(22) Filed: Jan. 5, 2026

(30) Foreign Application Priority Data
Jan. 23, 2025 (KR) 10-2025-0010301

(51) Int. Cl. H01J 37/22; H01J 37/244; H01J 37/285

(52) U.S. Cl. CPC H01J 37/228; H01J 37/244; H01J 37/285; H01J 2237/24475; H01J 2237/2448; H01J 2237/24564; H01J 2237/2482; H01J 2237/2485; H01J 2237/2812

(57) ABSTRACT

A substrate inspection apparatus may include a stage on which a substrate is to be provided; an electron beam apparatus configured to generate and emit an electron beam onto the substrate, a laser assembly configured to generate a first light having a predetermined wavelength, a lamp assembly including a light source configured to generate and emit a multi-wavelength light, and an optical filter configured to pass a second light having a target wavelength, among the multi-wavelength light; and a processor configured to determine the target wavelength and control the electron beam apparatus, the laser assembly, and the lamp assembly to radiate the first light, the second light, and the electron beam onto the substrate.

### CROSS-REFERENCE TO RELATED APPLICATION(S)

This application claims priority to Korean Patent Application No. 10-2025-0010301, filed on Jan. 23, 2025 in the Korean Intellectual Property Office, the disclosure of which is incorporated herein by reference in its entirety.

### BACKGROUND

The present disclosure relates to a substrate inspection apparatus and a substrate inspection system.

A scanning electron microscope (SEM) may detect defects in a substrate in a process of manufacturing a semiconductor device. When an electron beam is scanned over a specimen using a scanning electron microscope, secondary electrons (SE) or backscattered electrons (BSE) emitted from the specimen may be used to obtain information on a surface of the specimen or to obtain information on electrical characteristics and physical properties of the specimen.

### SUMMARY

One or more embodiments of the present disclosure provide a substrate inspection apparatus and a substrate inspection system.

According to an aspect of the present disclosure, a substrate inspection apparatus may include: a stage on which a substrate is to be provided; an electron beam apparatus configured to generate and emit an electron beam onto the substrate; a laser assembly configured to generate a first light having a predetermined wavelength; a lamp assembly including a light source configured to generate and emit a multi-wavelength light, and an optical filter configured to pass a second light having a target wavelength, among the multi-wavelength light; and a processor configured to determine the target wavelength and control the electron beam apparatus, the laser assembly, and the lamp assembly to radiate the first light, the second light, and the electron beam onto the substrate.

According to an aspect of the present disclosure, a substrate inspection system may include: a stage on which a substrate is to be provided; an electron beam apparatus configured to radiate an electron beam onto the substrate; a lamp assembly including a light source configured to generate and emit a multi-wavelength light, and an optical filter configured to pass a first light having a target wavelength, among the multi-wavelength light; and a processor configured to: control the lamp assembly to radiate a first auxiliary light having a first wavelength range, among the multi-wavelength light, onto a first region of the substrate; control the lamp assembly to radiate a second auxiliary light having a second wavelength range different from the first wavelength range, among the multi-wavelength light, onto a second region of the substrate; and determine the target wavelength, based on at least one of surface voltages and gray levels for the first region of the substrate and the second region of the substrate.

According to an aspect of the present disclosure, a substrate inspection apparatus may include: a stage on which a substrate is to be provided; an electron beam apparatus configured to radiate an electron beam onto the substrate; a laser assembly configured to radiate a first light having a predetermined wavelength onto the substrate; a lamp assembly including a light source configured to generate and emit a multi-wavelength light, and an optical filter configured to pass a second light having a target wavelength, among the multi-wavelength light; and a processor configured to determine the target wavelength, based on a material of a conductive pattern on the substrate, and control the electron beam apparatus, the laser assembly, and the lamp assembly to radiate the first light, the second light, and the electron beam onto the substrate.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1A is a schematic diagram illustrating a substrate inspection apparatus according to example embodiments of the present disclosure;

FIG. 1B is a schematic diagram illustrating a substrate inspection apparatus according to another example embodiment;

FIG. 2 is a plan view of the substrate in FIG. 1A according to one or more example embodiments;

FIG. 3A illustrates an electron beam and different types of light radiated onto the substrate in FIG. 1A according to one or more example embodiments;

FIG. 3B illustrates an electron beam and different types of light radiated onto the substrate in FIG. 1A according to another example embodiment;

FIG. 4 is a flowchart illustrating a substrate inspection method according to example embodiments of the present disclosure;

FIG. 5A is a flowchart illustrating a method of determining a target wavelength according to one or more example embodiments of the present disclosure;

FIG. 5B is a flowchart illustrating a method of determining a target wavelength according to another example embodiment of the present disclosure;

FIG. 6 is a flowchart illustrating a method of manufacturing a semiconductor device according to example embodiments of the present disclosure;

FIG. 7A is an image illustrating initial surface voltage distributions of respective regions of a substrate according to one or more example embodiments;

FIG. 7B is an image illustrating surface voltage distributions of respective regions of a substrate according to one or more example embodiments;

FIG. 8A is a graph illustrating a histogram of an initial surface voltage of a substrate according to one or more example embodiments;

FIG. 8B is a graph illustrating a histogram of a surface voltage of a substrate according to one or more example embodiments;

FIG. 9A is a graph illustrating initial surface voltage distributions of respective regions of a substrate according to one or more example embodiments;

FIG. 9B is a graph illustrating initial surface voltage distributions of respective regions of a substrate according to one or more example embodiments;

FIG. 9C is a graph illustrating surface voltage change amounts of respective regions of a substrate according to one or more example embodiments;

FIG. 10A is a graph illustrating gray levels of respective regions of a substrate according to one or more example embodiments;

FIG. 10B is a graph illustrating gray levels of respective regions of a substrate according to another example embodiment; and

FIG. 10C is a graph illustrating gray level change amounts of respective regions of a substrate according to one or more example embodiments.

### DETAILED DESCRIPTION

Hereinafter, preferred example embodiments of the present disclosure will be described in more detail with reference to the accompanying drawings. Identical reference numerals are used for the same components in the drawings, and repeated descriptions of the same components are omitted.

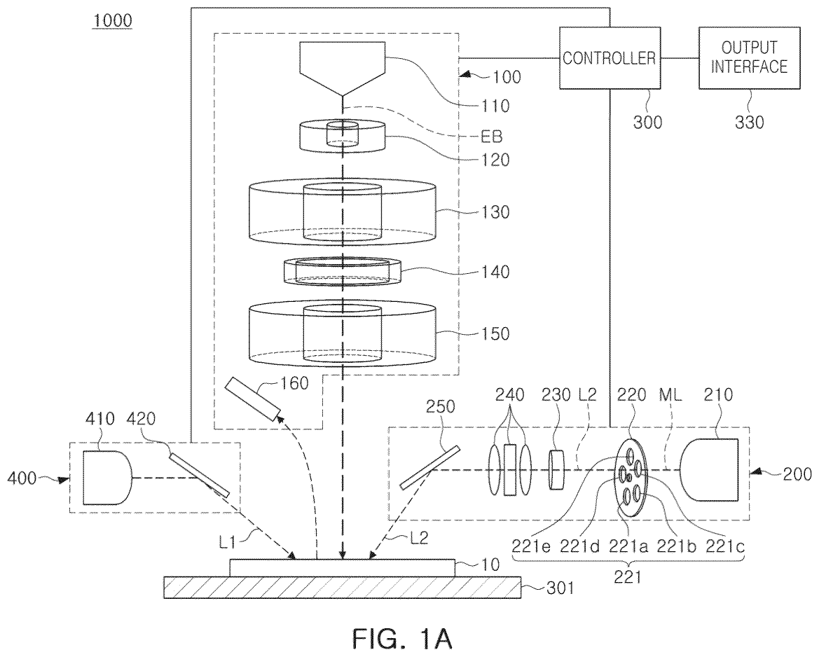

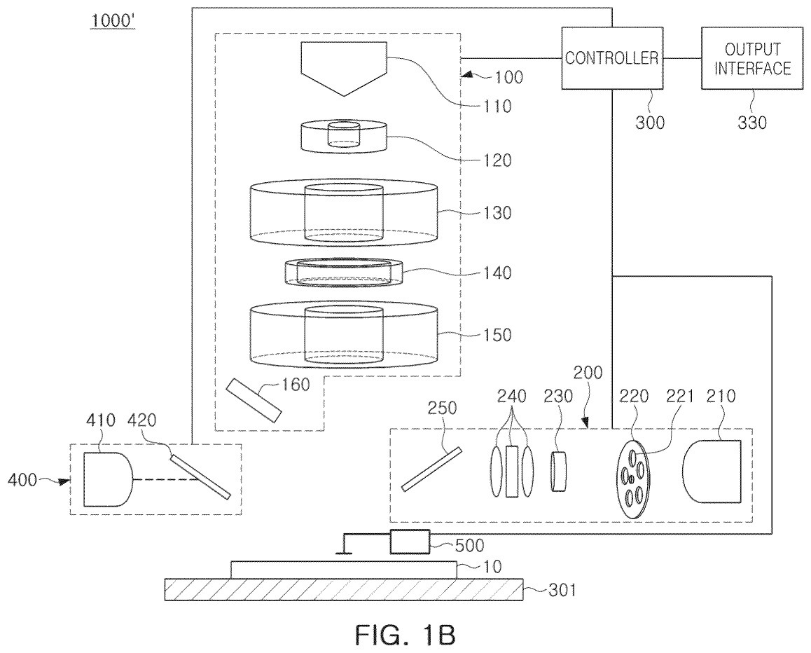

FIG. 1A is a schematic diagram illustrating a substrate inspection apparatus according to example embodiments of the present disclosure.

Referring to FIG. 1A, a substrate inspection apparatus 1000 may include a stage 301 on which a substrate 10 is provided, an electron beam apparatus 100 disposed on the stage 301, a lamp module (e.g., a lamp assembly including a non-laser light source) 200 and a laser module (e.g., a laser assembly including a laser source) 400 disposed between the stage 301 and the electron beam apparatus 100, a controller (e.g., a processor) 300 electrically connected to the stage 301, the electron beam apparatus 100, the lamp module 200, and the laser module 400, and an output interface 330 connected to the controller 300. The processor may refer to any computing device, processing unit, controller, or microprocessor capable of executing instructions stored in memory. The processor may include a single processing core or multiple cores. The processor may be implemented as a central processing unit (CPU), a digital signal processor (DSP), a graphics processing unit (GPU), a field-programmable gate array (FPGA), an application-specific integrated circuit (ASIC), or any combination thereof. The processor may reside in a single device or be distributed across multiple devices and may be configured to execute software, firmware, or hardware logic instructions.

The stage 301 may be a support structure on which the substrate 10 is disposed, and may be supported on an upper surface of the stage 301. The stage 301 may linearly move the substrate 10 in a horizontal direction and a vertical direction. The substrate 10, moved onto the stage 301, may be in a state in which processes of forming a thin film on an upper surface of the substrate and treating the formed thin film, and processes such as deposition, etching, photolithography, and cleaning, are performed thereon.

The electron beam apparatus 100 may include an inspection apparatus using an electron beam EB. For example, the electron beam apparatus 100 may include a scanning electron microscope (SEM) or an electron beam apparatus.

The electron beam apparatus 100 may include an electron gun 110, an acceleration electrode 120, a condensing lens 130, a scanning coil 140, an objective lens 150, and a detector 160.

The electron gun 110 may generate and emit an electron beam EB. The electron gun 110 may be a Schottky-type or thermionic emission-type electron gun. For example, the electron gun 110 may include a filament. When the filament is heated to a high temperature, electrons bound to atoms on a surface of the filament may be emitted. The electron beam EB, emitted by the electron gun 110, may pass through the acceleration electrode 120, the condensing lens 130, the scanning coil 140, and the objective lens 150, and may be radiated onto the substrate 10.

The acceleration electrode 120 may accelerate the electron beam EB emitted by the electron gun 110. The acceleration electrode 120 may include an anode electrode, and may accelerate the electron beam EB by applying a voltage to a space between the electron gun 110 and the acceleration electrode 120. In an example, the acceleration electrode 120 may be disposed between the electron gun 110 and the stage 301. In an example, the acceleration electrode 120 may be disposed below the electron gun 110, allowing the electron beam EB emitted by the electron gun 110 to pass therethrough.

The condensing lens 130 may focus the electron beam EB. The condensing lens 130 may have a cylindrical shape, but the embodiments are not limited thereto. The condensing lens 130 may include an electromagnet and/or capacitor, using Lorentz force applied to the electron beam EB in a magnetic field to adjust a direction of travel of the electron beam EB. The condensing lens 130 may be disposed between the acceleration electrode 120 and the stage 301, and the electron beam EB passing through the acceleration electrode 120 may pass through the condensing lens 130.

The scanning coil 140 may scan the electron beam EB in a one-dimensional or two-dimensional manner, such that the electron beam EB may be scanned over a desired region, on the substrate 10, a specimen. The scanning coil 140 may control a direction of scanning of the electron beam EB through a control signal. The scanning coil 140 may be disposed between the condensing lens 130 and the stage 301.

The objective lens 150 may focus the electron beam EB, deflected by the scanning coil 140, onto the substrate 10.

The detector 160 may detect electrons (hereinafter, secondary electrons and/or backscattered electrons) emitted from the substrate 10 by the electron beam EB. Information on an image of a substrate surface form, physical properties, and electrical characteristics of the substrate may be obtained through information on the secondary electrons and/or backscattered electrons. The detector 160 may be also referred to as an electron detector. The image of the substrate surface form may be a spatial image having two-dimensional information. Defects in the substrate 10 may be detected through the image. The detector 160 may transmit information on the secondary electrons and/or backscattered electrons to the controller 300.

To detect defects in the substrate 10, it may be necessary to minimize loss of the secondary electrons and/or backscattered electrons to secure data on the secondary electrons and/or backscattered electrons. A photoelectric effect may be used to minimize the loss of the secondary electrons and/or backscattered electrons.

To maximize the photoelectric effect, light may be radiated onto the substrate 10 using the lamp module 200 and the laser module 400. The lamp module 200 may include broadband, multi-wavelength light sources such as a xenon lamp, tungsten-halogen lamp, or white light-emitting diode (LED). These are incoherent light sources that emit a wide spectral range, in contrast to the laser module 400, which provides monochromatic and coherent illumination. In this context, the term “lamp” refers to non-laser light sources. The lamp module 200 and the laser module 400 may be positioned to avoid interfering with the electron beam emitted from the electron beam apparatus 100 and to provide complementary optical inspection capabilities.

To enhance the detection efficiency of secondary electrons and/or backscattered electrons by the detector 160, light may be radiated onto the substrate 10 using the lamp module 200 and the laser module 400. The radiated light may induce a photoelectric effect at the surface of the substrate 10, facilitating the emission of low-energy electrons that might otherwise be lost or reabsorbed. By increasing the number of electrons released from the surface of the substrate 10 through photon stimulation, the loss of secondary and/or backscattered electrons may be minimized. This may reduce signal loss and enhance the accuracy of defect detection and surface imaging.

The lamp module 200 and the laser module 400 may be disposed between the electron beam apparatus 100 and the stage 301. In an example, the electron beam apparatus 100 may be disposed above the area between the lamp module 200 and laser module 400. The lamp module 200 and laser module 400 may be disposed on one side of the electron beam's path between the stage 301 and electron beam apparatus 100 to avoid overlapping with the electron beam's movement.

The lamp module 200 may include a first light source 210, an optical filter 220, an optical modulator 230, an optical homogenizer 240, and a first light reflector 250. The first light reflector 250 may include at least one of a mirror, a reflective film, a retroreflector, or a diffuse reflector. The first light source 210, the optical filter 220, the optical modulator 230, the optical homogenizer 240, and the first light reflector 250 may be sequentially disposed in the horizontal direction.

The first light source 210 may generate and emit multi-wavelength light ML. The multi-wavelength light ML, broadband light, may be multi-color light including light having a plurality of wavelength bands. The first light source 210 may include a light source lamp, such as a xenon lamp, tungsten-halogen lamp, or white light emitting diode. For example, the first light source 210 may be a xenon lamp radiating light having a broadband wavelength. For example, the broadband wavelength may range from about 220 nm to about 2000 nm.

The optical filter 220 may select one of a plurality of wavelength ranges. The optical filter 220 may include a filter wheel including optical filters 221. The optical filters 221 may filters for respectively allowing light having different wavelength ranges to pass therethrough. Among the multi-wavelength light ML emitted by the first light source 210, target light L2 having a predetermined wavelength range may pass through the optical filter 220. For example, the number of optical filters 221 may be five. The optical filters 221 may include a first optical filter 221a allowing light having a first wavelength range to pass therethrough, a second optical filter 221b allowing light having a second wavelength range to pass therethrough, a third optical filter 221c allowing light having a third wavelength range to pass therethrough, a fourth optical filter 221d allowing light having a fourth wavelength range to pass therethrough, and a fifth optical filter 221e allowing light having a fifth wavelength range to pass therethrough. The first to fifth wavelength ranges may be different wavelength ranges. However, the number of optical filters 221 is not limited to five, and it may also be four or less, or six or more.

The optical filter 220 may rotate to select one of a plurality of optical filters 221 according to a control signal of the controller 300. Accordingly, an optical filter corresponding to light having a target wavelength, among the multi-wavelength light ML emitted by the first light source 210, may be selected from among the optical filters 221, such that the light having the target wavelength may pass therethrough. For example, when the control signal of the controller 300 is a control signal selecting light having the first wavelength range, the first optical filter 221a allowing the light having the first wavelength range to pass therethrough may be selected.

The optical filter 220 may be disposed to be spaced apart from the first light source 210 in the horizontal direction and to be adjacent to the stage 301.

The optical modulator 230 may adjust a light amount of the target light L2 passing through the optical filter 220. The optical modulator 230 may include a neutral density filter. The light amount of the target light L2 may be adjusted by adjusting a transmittance of the neutral density filter. The optical modulator 230 may be spaced apart from the optical filter 220 in the horizontal direction, and may be disposed to be adjacent to the stage 301. The optical modulator 230 may be disposed between the optical homogenizer 240 and the optical filter 220.

The optical homogenizer 240 may allow the target light L2 passing through the optical modulator 230 to be radiated onto the substrate 10 with a uniform density. That is, a density of the target light L2 having a predetermined range may be controlled, such that the target light L2 may be uniformly radiated onto each region of the substrate 10. The optical homogenizer 240 may include a beam homogenizer. The optical homogenizer 240 may include a plurality of lenses. The optical homogenizer 240 may be disposed between the first light reflector 250 and the optical modulator 230.

The target light L2, passing through the optical homogenizer 240, may be reflected by the first light reflector 250 and radiated onto the substrate 10. An incident position of the target light L2 having a predetermined wavelength range may be controlled using the first light reflector 250.

The controller 300 may determine a target wavelength of light radiated onto the substrate 10 using the lamp module 200, based on a material of the conductive pattern on the substrate 10, and may control the optical filter 220 of the lamp module 200, such that the target light L2 having the target wavelength, among the multi-wavelength light ML, passes through the optical filter 220. For example, when the first conductive pattern is formed on the substrate 10 through a first semiconductor process, the controller 300 may select a first target wavelength to inspect the substrate 10 on which the first conductive pattern is formed. A value of the first target wavelength may be determined using a target wavelength determination method, but the embodiments are not limited thereto, and may be a data value pre-stored in the controller 300. When a second conductive pattern is formed on the substrate 10 through a second semiconductor process, distinguished from the first semiconductor process, the controller 300 may select a second target wavelength, distinguished from the first target wavelength, in order to inspect the substrate 10 on which a second conductive pattern is formed. A value of the second target wavelength may be determined using the target wavelength determination method, but the embodiments are not limited thereto, and may be a data value pre-stored in the controller 300. The pre-stored data value may be a data value according to a lookup table.

The laser module 400 may include a second light source 410 and a second light reflector 420. The second light reflector 420 may include at least one of a mirror, a reflective film, a retroreflector, or a diffuse reflector. The second light source 410 may be a laser light source. The second light source 410 may be a laser light source having a predetermined wavelength. The laser light source may be laser light L1 having a predetermined wavelength range. The laser light L1 having the predetermined wavelength range may be a fixed value. The laser light L1 having the predetermined wavelength range may be reflected by the second light reflector 420 and radiated onto the substrate 10. An incident position of the laser light L1 having the predetermined wavelength range may be controlled using the second light reflector 420. In another example embodiment, the laser module 400 may be omitted from the substrate inspection apparatus 1000. In this case, only the electron beam EB may be radiated onto the substrate using the electron beam apparatus 100, and only the target light L2 having the predetermined wavelength range may be radiated onto the substrate 10 using the lamp module 200. In the present disclosure, the laser light L1 may be referred to as first light.

The controller 300 may be electrically connected to the electron beam apparatus 100, the lamp module 200, and the laser module 400. The controller 300 may determine a target wavelength of light to be radiated onto the substrate 10 using the lamp module 200 to inspect the substrate 10 on the stage 301, and may control the electron beam apparatus 100 and the lamp module 200 to allow the target light L2 having the target wavelength and the electron beam EB to be radiated onto the substrate 10. The target wavelength may be a wavelength for minimizing loss of emitted electrons and effectively using a photoelectric effect. The target wavelength may have a value varying depending on the material of the conductive pattern on the substrate 10. In another example embodiment, the target wavelength may have a value varying depending on information desired to be obtained through the substrate inspection apparatus 1000. For example, when the substrate 10 on which a specific conductive pattern is formed operates in a mode of obtaining surface information, the first target wavelength, stored in the controller 300, may be selected in response thereto. When the substrate 10 on which the specific conductive pattern is formed operates in a mode of obtaining electrical characteristic information, the second target wavelength, stored in the controller 300, may be selected in response thereto.

The electron beam apparatus 100 may radiate the electron beam EB onto the substrate 10 in response to the control signal of the controller 300. The detector 160 of the electron beam apparatus 100 may detect secondary electrons and backscattered electrons emitted from the substrate 10, and transmit information on the secondary electrons and backscattered electrons to the controller 300. The controller 300 may form numerical data on a yield of the secondary electrons and backscattered electrons, based on the information on the secondary electrons and the backscattered electrons received from the electron beam apparatus 100, data indicating electrical characteristics based on the information on the backscattered electrons, and an SEM image indicating a surface form of the substrate 10. In an example, the controller 300 may also form an SEM image indicating a gray level of a surface of the substrate 10. The numerical data on the yield of the secondary electrons, the data indicating electrical characteristics based on the information on the backscattered electrons, the SEM image indicating the surface form of the substrate 10, and/or the SEM image indicating the gray level of the surface of the substrate 10, formed by the controller 300, may be output by an output interface 330 connected to the controller 300.

The output interface 330 may be used to output a video signal or a data signal. The output interface 330 may include a display, a speaker, a communication interface configured to transmit the video signal or the data signal to an external electronic assembly, or the like. For example, the be communication interface implemented by any one or any combination of a digital modem, a radio frequency (RF) modem, an antenna circuit, a WiFi chip, and related software and/or firmware

FIG. 1B is a schematic diagram illustrating a substrate inspection apparatus according to another example embodiment.

Referring to FIG. 1B, a substrate inspection apparatus 1000′ may include a stage 301 on which a substrate 10 is provided, an electron beam apparatus 100 on the stage 301, a lamp module 200 and a laser module 400 disposed between the stage 301 and the electron beam apparatus 100, a controller 300 electrically connected to the stage 301, the electron beam apparatus 100, the lamp module 200, and the laser module 400, an output interface 330 connected to the controller 300, and a surface voltage measurement module 500. The substrate inspection apparatus 1000′ may be a substrate inspection apparatus further including a surface voltage measurement module 500 as compared to the substrate inspection apparatus 1000 in FIG. 1A.

The surface voltage measurement module 500 may be electrically connected to the controller 300. The surface voltage measurement module 500 may measure a surface voltage of the substrate 10 in response to a control signal of the controller 300. The surface voltage measurement module 500 may be implemented using a capacitive electrode. In an example, the controller 300 may measure an initial surface voltage of the substrate 10 using the surface voltage measurement module 500. That is, the controller 300 may measure the initial surface voltage after the substrate 10 is provided on the stage 301. In an example, the controller 300 may measure the surface voltage of the substrate 10 after laser light L1, target light L2, and an electron beam EB are radiated onto the substrate 10. After the laser light L1, the target light L2, and the electron beam EB are radiated onto the substrate 10, the surface voltage of the substrate 10 may be changed.

As used herein, the substrate inspection apparatuses 1000 and 1000′ may be referred to as a substrate inspection system.

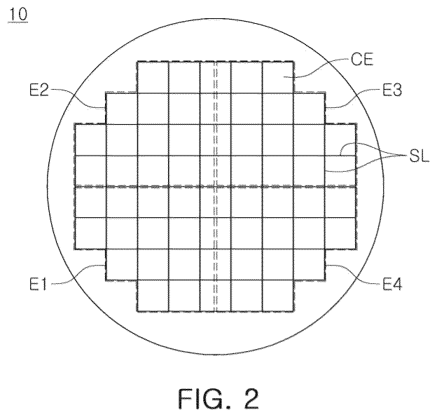

FIG. 2 is a plan view of the substrate in FIG. 1A according to one or more example embodiments.

FIG. 2 illustrates the substrate 10 as an example of an object to be inspected by the substrate inspection apparatus 1000 in FIG. 1A. The substrate 10 may be a wafer including a plurality of dies CE. Each of the plurality of dies CE may be a semiconductor chip. The plurality of dies CE may be divided by a scribe lane SL. The scribe lane SL may be a region for separating the substrate 10, on which a semiconductor device is formed, into the plurality of dies CE. The substrate 10 may include first to fourth regions E1 to E4 respectively including at least one die CE. For example, the first region E1 may include a plurality of first dies, the second region E2 may include a plurality of second dies, the third region E3 may include a plurality of third dies, and the fourth region E4 may include a plurality of fourth dies.

The substrate 10 may include a semiconductor material, for example, a group IV semiconductor, a group III-V compound semiconductor, or a group II-VI compound semiconductor. The substrate 201 may be provided as a bulk wafer or an epitaxial layer. For example, the substrate 201 may be bulk silicon or a silicon-on-insulator (SOI).

Referring to FIGS. 1A and 2, surface defect inspection may be performed on each of the dies CE or the regions E1 to E4 of the substrate 10 using the substrate inspection apparatus 1000. In an example, an inspection region of the substrate inspection apparatus 1000 may be at least one die CE of the substrate 10. For example, when the inspection region of the substrate inspection apparatus 1000 is one die CE of the substrate 10, the surface defect inspection may be performed on the one die CE by radiating the laser light L1, the target light L2, and the electron beam EB to the one die. In another example embodiment, when the inspection region of the substrate inspection apparatus 1000 is the first region E1, the surface defect inspection may be performed on the first region E1 by radiating the laser light L1, the target light L2, and the electron beam EB onto the first region E1.

Light having different wavelength ranges may be radiated onto the plurality of regions E1 to E4 of the substrate 10 using the lamp module 200. As target lights having different wavelength ranges are radiated onto the plurality of regions E1 to E4 using the lamp module 200, data on secondary electrons and backscattered electrons and/or data on a surface potential of the substrate 10 may be obtained to correspond to each of the plurality of regions E1 to E4.

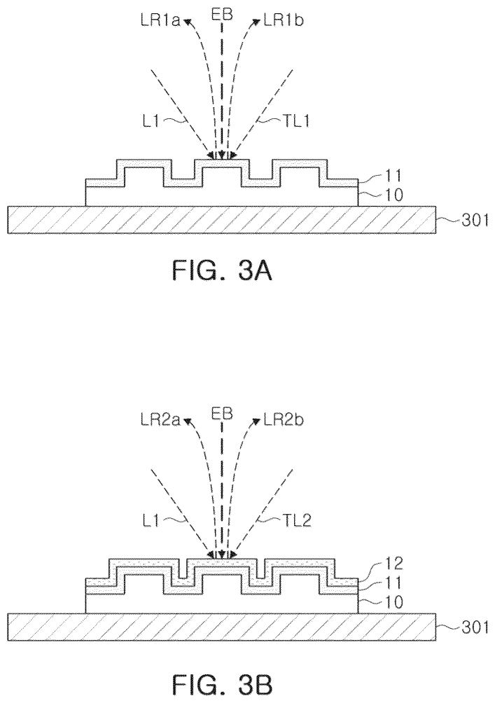

FIG. 3A illustrates an electron beam and different types of light radiated onto the substrate in FIG. 1A according to one or more example embodiments, and FIG. 3B illustrates an electron beam and different types of light radiated onto the substrate in FIG. 1A according to another example embodiment.

FIG. 3A illustrates electron beams and light radiated onto the substrate 10 for defect inspection performed on the substrate 10 when a first conductive pattern 11 is disposed on the substrate 10, and FIG. 3B illustrates electron beams and light radiated onto the substrate 10 for defect inspection performed on the substrate 10 when the first conductive pattern 11 and a second conductive pattern 12 are sequentially disposed on the substrate 10.

A controller (for example, the controller 300 in FIG. 1A) may determine light having a target wavelength to be radiated using a lamp module (for example, the lamp module 200 in FIG. 1A).

Referring to FIGS. 1A and 3A, after the first conductive pattern 11 is formed on the substrate 10 in a process of manufacturing a semiconductor device, first surface defect inspection may be performed on the substrate 10. For the first surface defect inspection, an electron beam EB, first light L1 having a predetermined wavelength range, and first target light TL1 having a first target wavelength may be radiated onto the substrate 10 using a substrate inspection apparatus (the substrate inspection apparatus 1000 in FIG. 1A). Prior to performing the first surface defect inspection, the controller 300 may determine the first target wavelength. As the electron beam EB, the first light L1 having the predetermined wavelength range, and the first target light TL1 having the first target wavelength are radiated onto the substrate 10, a second secondary electron LR1a and a backscattered electron LR1b may be detected using the detector 160. The controller 300 may detect defects in the substrate 10 having an upper surface on which the first conductive pattern 11 is formed, based on information on the detected secondary electron LR1a and backscattered electron LR1b.

Referring to FIGS. 1A and 3B, after the second conductive pattern 12 is formed on the first conductive pattern 11 formed on an upper surface of the substrate 10 in a process of manufacturing a semiconductor device, second surface defect inspection may be performed on the substrate 10 using the substrate inspection apparatus 1000 in FIG. 1A. For the second surface defect inspection, an electron beam EB, first light L1 having a predetermined wavelength range, and second target light TL2 having a second target wavelength, different from the first target wavelength, may be radiated onto the substrate 10. Prior to performing the second surface defect inspection, the controller 300 may determine the second target wavelength. As the electron beam EB, the first light L1 having the predetermined wavelength range, and the second target light TL2 having the second target wavelength are radiated onto the substrate 10, a second secondary electron LR2a and a backscattered electron LR2b may be detected using the detector 160. The controller 300 may detect surface defects in the substrate 10 having the upper surface on which the second conductive pattern 12 is formed, based on information on the detected second secondary electron LR2a and backscattered electron LR2b.

In the surface defect inspection performed on the substrate 10, the electron beam EB, radiated using the electron beam apparatus 100, and the first light L1, radiated using the laser module 400, may be light having a constant wavelength range regardless of a semiconductor manufacturing process operation performed on the substrate 10.

The target light L2 having the target wavelength, radiated using the lamp module 200 in the surface defect inspection performed on the substrate 10, may have a wavelength range varying depending on each semiconductor manufacturing process operation performed on the substrate 10.

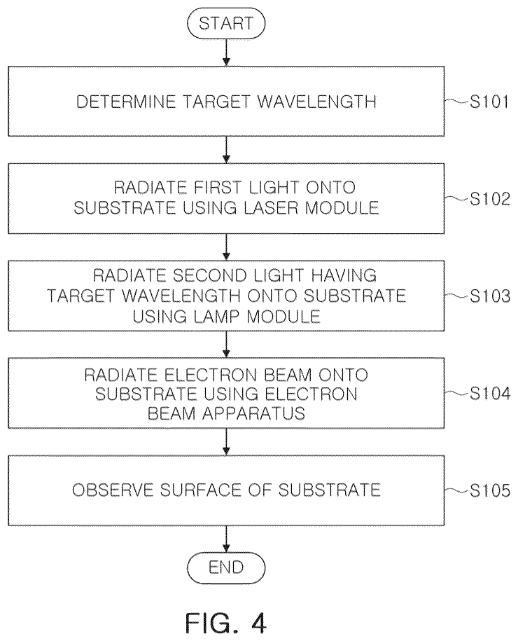

FIG. 4 is a flowchart illustrating a substrate inspection method according to example embodiments of the present disclosure.

Referring to FIG. 4, the substrate inspection method may be performed by the substrate inspection apparatus 1000 in FIG. 1A or the substrate inspection apparatus 1000′ in FIG. 1B.

The substrate inspection method according to example embodiments of the present disclosure may include an operation (S101) of determining a target wavelength, operations (S102, S103, and S104) of radiating first light L1, second light L2 having a target wavelength, and an electron beam EB onto a substrate 10, and an operation (S105) of observing a surface of the substrate 10.

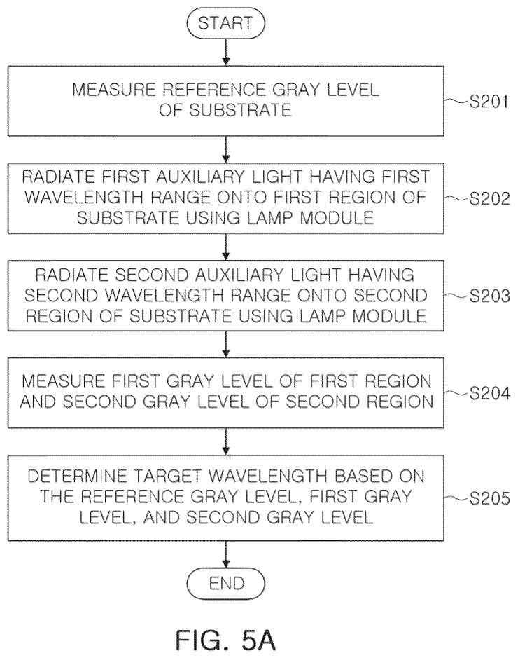

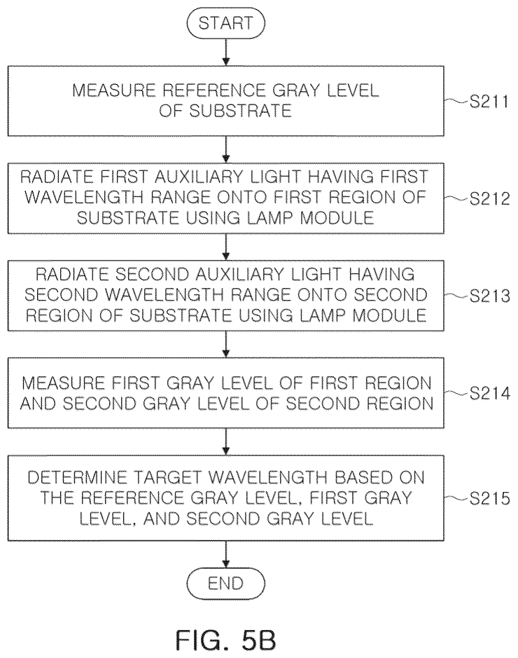

In one or more example embodiments, in operation S101, the substrate inspection apparatus 1000 may determine a target wavelength. In one or more example embodiments, a controller 300 may radiate different types of light having different wavelength ranges for respective regions of the substrate 10 using a lamp module 200, and may measure surface voltages for the respective regions of the substrate 10 after radiating the different types of light for the respective regions of the substrate 10. In addition, the controller 300 may calculate gray level values (e.g., intensity values) of detected electrons for the respective regions of the substrate 10 after radiating the different types of light for the respective regions of the substrate 10. The controller 300 may determine a target wavelength, based on at least one of the surface voltages and the gray levels measured with respect to the respective regions. In an example, the controller 300 may determine the target wavelength by comparing a reference surface voltage of the substrate 10 with the surface voltages for the respective regions of the substrate 10. In another example, the target wavelength may be determined by comparing the reference gray level of the substrate 10 with the gray level values for the respective regions of the substrate 10. A method of determining the target wavelength will be described with reference to FIGS. 5A and 5B to be described below.

In one or more example embodiments, in operation S102, the substrate inspection apparatus 1000 may radiate first light L1 onto the substrate 10 using a laser module 400. In operation S103, the substrate inspection apparatus 1000 may radiate second light L2 having the determined target wavelength onto the substrate 10 using the lamp module 200. The second light L2 may be radiated onto the substrate 10 together with the first light L1. In an example, the second light L2 may be radiated onto the substrate 10 after a predetermined time elapses after the first light L1 starts to be radiated onto the substrate 10. In another example, the second light L2 may be radiated onto the substrate 10 simultaneously with the first light L1.

In one or more example embodiments, in operation S104, in the substrate inspection apparatus 1000, an electron beam EB may be radiated onto the substrate 10 using an electron beam apparatus 100 in a state in which the first light L1 and the second light L2 are radiated onto the substrate 10. In an example, as the first light L1, the second light L2, and the electron beam EB are radiated onto the substrate 10, secondary electrons and/or backscattered electrons may be emitted from a surface of the substrate 10 and detected using a detector 160. In one or more example embodiments, in operation S105, the substrate inspection apparatus 1000 may detect a defect in the surface of the substrate 10 by observing the surface of the substrate 10, based on data on the secondary electrons and/or backscattered electrons detected using the detector 160.

FIG. 5A is a flowchart illustrating a method of determining a target wavelength according to one or more example embodiments of the present disclosure.

Referring to FIG. 5A, the method of determining a target wavelength according to example embodiments of the present disclosure may include an operation (S201) of measuring a reference gray level of a substrate 10, an operation (S202) of radiating first auxiliary light having a first wavelength range onto a first region (for example, the first region E1 in FIG. 2) of the substrate 10 using a lamp module 200, an operation (S203) of radiating second auxiliary light having a second wavelength range using the lamp module 200 (for example, the second region E2 in FIG. 2) of the substrate 10, an operation (S204) of measuring a first gray level of the first region E1 and a second gray level of the second region E2, and an operation (S205) of determining the target wavelength based on the reference gray level, the first gray level, and the second gray level.

In one or more example embodiments, in operation S201, the substrate inspection apparatus 1000 in FIG. 1A may measure a reference gray level of the substrate 10. The reference gray level of the substrate 10 may be measured using an SEM image provided before first auxiliary light and second auxiliary light are radiated onto the substrate 10 in operations S202 and S203. The reference gray level may be referred to as an initial gray level. The reference gray level may be an average value of reference gray levels of the substrate 10. As used herein, the gray level may be a value representing brightness of each pixel of the SEM image.

In one or more example embodiments, in operation S202, the substrate inspection apparatus 1000 may emit first auxiliary light having a first wavelength range onto a first region E1 of the substrate 10 using the lamp module 200. The first wavelength range may be a wavelength range in which light, among multi-wavelength light ML emitted by a first light source 210 of the lamp module 200, passes through an optical filter 220 according to a control signal of a controller 300. The first region of the substrate 10 may correspond to the first region E1 in FIG. 2, but the embodiments are not limited thereto. In another example, the first region of the substrate 10 may be a single die CE. The substrate inspection apparatus 1000 may emit an electron beam EB onto the first region E1 of the substrate 10 using an electron beam apparatus 100 in response to an operation of radiating the first auxiliary light onto the first region of the substrate 10. The first auxiliary light having the first wavelength range may be radiated onto the first region E1 of the substrate 10 together with the electron beam EB.

In one or more example embodiments, in operation S203, the substrate inspection apparatus 1000 may irradiate a second region E2 of the substrate 10 with second auxiliary light having a second wavelength range, different from the first wavelength range, using the lamp module 200. The second wavelength range may be a wavelength range in which light, among the multi-wavelength light ML emitted by the first light source 210 of the lamp module 200, passes through the optical filter 220 according to a control signal of the controller 300. The second region of the substrate 10, a region distinguished from the first region of the substrate 10, may correspond to the second region E2 in FIG. 2, but the embodiments are not limited thereto. In another example, the second region of the substrate 10 may be another single die CE. The substrate inspection apparatus 1000 may radiate the electron beam EB onto the second region E2 of the substrate 10 using the electron beam apparatus 100 in response to an operation of radiating the second auxiliary light onto the second region of the substrate 10. The second auxiliary light having the second wavelength range may be radiated onto the second region E2 of the substrate 10 together with the electron beam EB.

In one or more example embodiments, in operation S204, the substrate inspection apparatus 1000 may measure a first gray level of the first region E1 and a second gray level of the second region E2. In an example, the first gray level of the first region E1 may be measured using an SEM image transmitted from the electron beam apparatus 100 to the controller 300 after operation S202 is performed. The second gray level of the second region E2 may be measured using the SEM image transmitted from the electron beam apparatus 100 to the controller 300 after operation S203 is performed. The first gray level of the first region E1 of the substrate 10 may be an average value of gray levels of the first region E1. The second gray level of the second region E2 of the substrate 10 may be an average value of gray levels of the second region E2.

In one or more example embodiments, in operation S205, the substrate inspection apparatus 1000 may determine a target wavelength, based on the reference gray level, the first gray level, and the second gray level. The controller 300 may calculate a change amount (hereinafter referred to as a change amount of the first gray level) between the reference gray level and the first gray level, and a change amount (hereinafter referred to as a change amount of the second gray level) between the gray level and the second gray level.

In one or more example embodiments, when the first gray level change amount is greater than the second gray level change amount, the controller 300 may determine the first wavelength range of the first auxiliary light as the target wavelength. That is, when the first light L1, the second light L2 having the first wavelength range, and the electron beam EB are radiated onto the substrate 10 for defect inspection of the substrate 10, data (hereinafter, first measurement data) on secondary electrons and backscattered electrons emitted from a surface of the substrate 10 may be obtained. When the first light L1, the second light L2 having the second wavelength range, and the electron beam EB are radiated onto the substrate 10 for surface defect inspection of the substrate 10, data on secondary electrons and backscattered electrons emitted from the surface of the substrate 10 (hereinafter, second measurement data) may be obtained. The first measurement data may be reliable measurement data according to a photoelectric effect, and thus may be more effective than the second measurement data in determining defects in the surface of the substrate 10.

In another example embodiment, when the first gray level change amount is greater than the second gray level change amount, the second wavelength range of the second auxiliary light may be determined as the target wavelength. In this case, the second measurement data may be reliable measurement data according to a photoelectric effect, and thus may be more effective than the first measurement data in determining defects in the surface of the substrate 10.

FIG. 5B is a flowchart illustrating a method of determining a target wavelength according to another example embodiment of the present disclosure.

Referring to FIG. 5B, the method of determining a target wavelength according to another example embodiment of the present disclosure may include an operation (S211) of measuring a reference surface voltage of a substrate 10, an operation (S212) of radiating first auxiliary light having a first wavelength range onto a first region (for example, the first region E1 in FIG. 2) of the substrate 10 using a lamp module 200, an operation (S213) of radiating second auxiliary light having a second wavelength range onto a second region of (for example, the second region E2 in FIG. 2) of the substrate 10, an operation (S214) of measuring a first surface voltage of the first region E1 and a second surface voltage of the second region E2, and an operation (S215) of determining the target wavelength, based on the reference surface voltage, the first surface voltage, and the second surface voltage.

In one or more example embodiments, in operation S211, the substrate inspection apparatus 1000′ in FIG. 1B may measure a reference surface voltage of the substrate 10. The reference surface voltage of the substrate 10 may be measured prior to an operation of radiating first auxiliary light and second auxiliary light onto the substrate 10, performed in operations S212 and S213 using the surface voltage measurement module 500 in FIG. 1B. The reference surface voltage may be referred to as an initial surface voltage. The reference surface voltage may be an average value of surface voltage values of the substrate 10 before the first auxiliary light and the second auxiliary light are radiated onto the substrate 10.

In one or more example embodiments, in operation S212, the substrate inspection apparatus 1000′ may radiate first auxiliary light having a first wavelength range onto a first region E1 of the substrate 10 using the lamp module 200. Operation S212 may correspond to operation S202 in FIG. 5A.

In one or more example embodiments, in operation S213, the substrate inspection apparatus 1000′ may irradiate the second region E2 of the substrate 10 with second auxiliary light having a second wavelength range different from the first wavelength range, using the lamp module 200. Operation S213 may correspond to operation S203 in FIG. 5B.

In one or more example embodiments, in operation S214, the substrate inspection apparatus 1000′ may measure a first surface voltage of the first region E1 and a second surface voltage of the second region E2. In an example, the surface voltage measurement module 500 may measure the first surface voltage of the first region E1 and the second surface voltage of the second region E2 by measuring a surface voltage of the substrate 10 after an operation of radiating the first auxiliary light onto the first region E1 and radiating the second auxiliary light onto the second region E2. As different types of light having different wavelength ranges are respectively radiated onto the first and second regions E1 and E2 of the substrate 10, surface voltage values for the first and second regions E1 and E2 of the substrate 10 may be different from each other. The first surface voltage of the first region E1 of the substrate 10 may be an average value of first surface voltage values measured with respect to the first region E1. The second surface voltage of the second region E2 of the substrate 10 may be an average value of second surface voltage values measured with respect to the second region E2.

In one or more example embodiments, in operation S215, the substrate inspection apparatus 1000′ may determine a target wavelength, based on the reference surface voltage, the first surface voltage, and the second surface voltage. The controller 300 may calculate a change amount (for example, a first surface voltage change amount) of the reference surface voltage and the first surface voltage and a change amount (for example, a second surface voltage change amount) of the reference surface voltage and the second surface voltage. In an example, the controller 300 may determine the first wavelength range of the first auxiliary light as the target wavelength when the first surface voltage change amount is greater than the second surface voltage change amount. In another example, the controller 300 may determine the second wavelength range of the second auxiliary light as the target wavelength when the second surface voltage change amount is greater than the first surface voltage change amount.

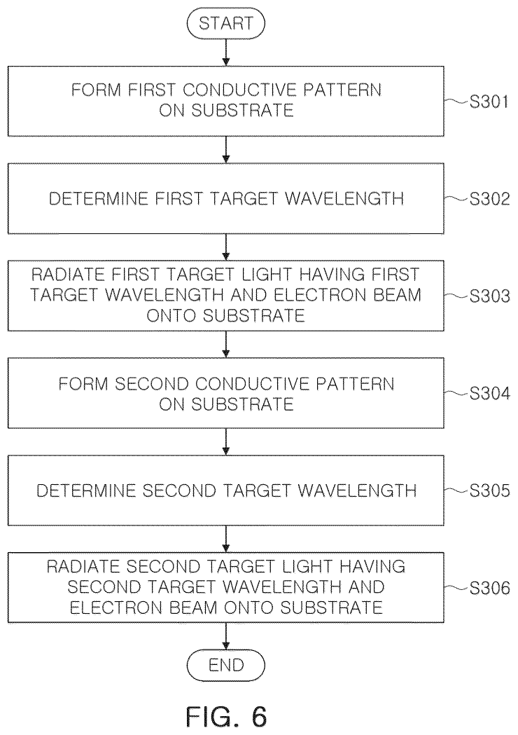

FIG. 6 is a flowchart illustrating a method of manufacturing a semiconductor device according to example embodiments of the present disclosure.

Referring to FIG. 6 together with FIG. 3A and FIG. 3B, the method of manufacturing a semiconductor device according to example embodiments of the present disclosure may include an operation (S301) of forming a first conductive pattern (for example, the first conductive pattern 11 in FIG. 3A) on a substrate 10, an operation (S302) of determining a first target wavelength, an operation (S303) of radiating first target light TL1 having the first target wavelength and an electron beam EB of onto the substrate 10, an operation (S304) of forming a second conductive pattern (for example, the second conductive pattern 12 in FIG. 3B) on the substrate 10, an operation (S305) of determining a second target wavelength, and an operation (S306) of radiating second target light TL2 having the second target wavelength and the electron beam EB onto the substrate 10.

In one or more example embodiments, in operation S301, the first conductive pattern 11 may be formed on the substrate 10. In an example, the operation of forming the first conductive pattern 11 on the substrate 10 may include various process operations of forming semiconductor devices on the substrate 10. For example, the operation of forming the first conductive pattern 11 on the substrate 10, a first process operation of a semiconductor device, may refer to a process of forming a contact plug connected to a source/drain region (not illustrated) formed in the substrate 10.

In one or more example embodiments, operations S302 and S303 may be operations for detection of defects in a surface of the substrate 10 on which the first conductive pattern 11 is formed. In operation S302, a first target wavelength may be determined using the substrate inspection apparatus 1000′ in FIG. 1A or the substrate inspection apparatus 1000′ in FIG. 1B. A method of determining the first target wavelength may follow the method of determining the target wavelength described with reference to FIG. 5A or 5B.

In one or more example embodiments, in operation S303, for surface defect inspection of the substrate 10 having an upper surface on which the first conductive pattern 11 is formed, first target light TL1 having the first target wavelength may be radiated onto the substrate 10 using a lamp module 200, and an electron beam EB may be radiated onto the substrate 10 using an electron beam apparatus 100. A controller 300 may transmit a control signal to the lamp module 200 to radiate the first target light TL1 having the first target wavelength determined in operation S302 onto the substrate 10. The lamp module 200 may receive the control signal and control an optical filter 220 to allow the first target light TL1 having the first target wavelength, among the multi-wavelength light ML, to pass therethrough. In one or more example embodiments, as the first target light TL1 having the first target wavelength and the electron beam EB are radiated onto the substrate 10, a second secondary electron LR1a and a backscattered electron LR1b may be detected using a detector 160. Based on information on the detected secondary electron LR1a and backscattered electron LR1b, whether surface defects are present in the substrate 10 having the upper surface on which the first conductive pattern 11 is formed may be determined.

In one or more example embodiments, in operation S304, a second conductive pattern 12 may be formed on the substrate 10. The second conductive pattern 12 may be formed on the first conductive pattern 11. An operation of forming the second conductive pattern 12 on the substrate 10, a subsequent process operation for operation S301, may be a second process operation of the semiconductor device. In an example, the first conductive pattern 11 may include a first conductive material, and the second conductive pattern 12 may include a second conductive material, different from the first conductive material.

In one or more example embodiments, operations S305 and S306 may be inspection operations for the substrate 10 on which the second conductive pattern 12 is formed. In operation S305, a second target wavelength may be determined using the substrate inspection apparatus 1000′ in FIG. 1A or the substrate inspection apparatus 1000′ in FIG. 1B. A method of determining the second target wavelength may follow the method of determining the target wavelength described with reference to FIG. 5A or 5B.

In one or more example embodiments, in operation S306, for surface defect inspection for the substrate 10 having an upper surface on which the second conductive pattern 12 is formed, emitted second target light TL2 having the second target wavelength may be radiated onto the substrate 10 using the lamp module 200, and an electron beam EB may be radiated onto the substrate 10 using the electron beam apparatus 100. The controller 300 may transmit a control signal to the lamp module 200 to radiate the second target light TL2 having the second target wavelength determined in operation S305 onto the substrate 10. The lamp module 200 may receive the control signal and control the optical filter 220 to pass the second target light TL2 having the second target wavelength, among the multi-wavelength light ML, to pass therethrough. In one or more example embodiments, as the second target light TL2 having the second target wavelength and the electron beam EB are radiated onto the substrate 10, a second secondary electron LR2a and a backscattered electron LR2b may be detected using the detector 160. Based on information on the detected secondary electron LR2a and backscattered electron LR2b, whether surface defects are present in the substrate 10 having the upper surface on which the second conductive pattern 12 is formed may be determined.

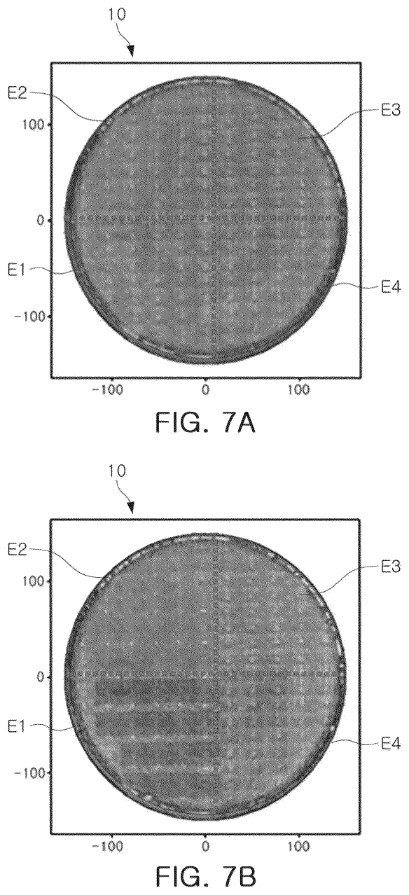

FIG. 7A is an image illustrating initial surface voltage distributions of respective regions of a substrate according to one or more example embodiments. FIG. 7B is an image illustrating surface voltage distributions of respective regions of a substrate according to one or more example embodiments.

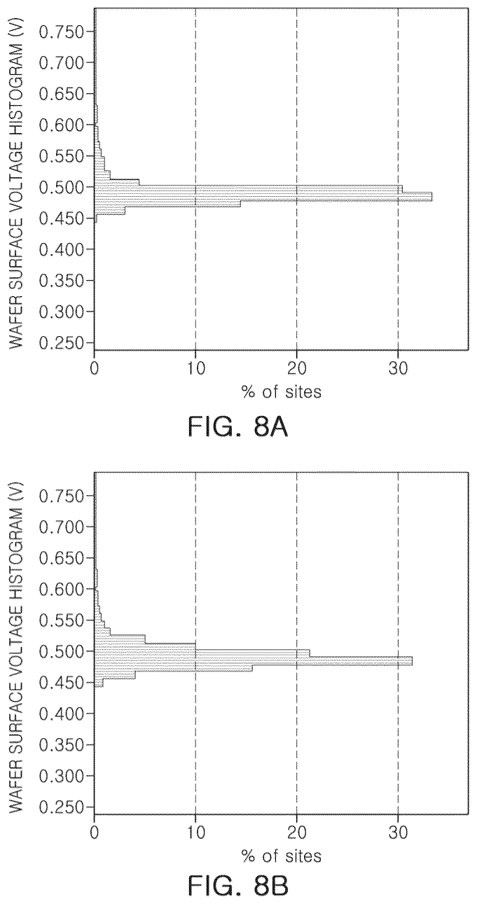

FIG. 8A is a graph illustrating a histogram of an initial surface voltage of a substrate according to one or more example embodiments. FIG. 8B is a graph illustrating a histogram of a surface voltage of a substrate according to one or more example embodiments. FIG. 8A illustrates distribution of initial surface voltages of the substrate 10, and FIG. 8B illustrates distribution of surface voltages of the substrate 10.

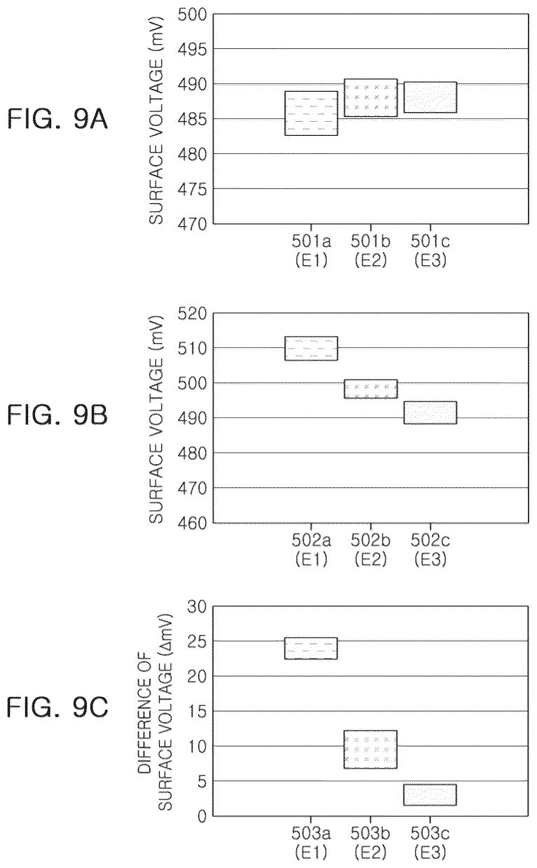

FIG. 9A is a graph illustrating initial surface voltage distributions of respective regions of a substrate according to one or more example embodiments. FIG. 9B is a graph illustrating initial surface voltage distributions of respective regions of a substrate according to one or more example embodiments. FIG. 9C is a graph illustrating surface voltage change amounts of respective regions of a substrate according to one or more example embodiments.

Referring to FIGS. 7A, 8A, and 9A, graph 501a may represent initial surface voltage values of a first region E1 of a substrate 10, graph 501b may represent initial surface voltage values of a second region E2 of the substrate 10, and graph 501c may represent initial surface voltage values of a third region E3 of the substrate 10. In an example, average values of initial surface voltage values of each of the first to fourth regions E1 to E4 of the substrate 10 may be substantially the same. An initial surface voltage of the substrate 10 may be about 487 mV. An average value of the initial surface voltage values measured with respect to the first region E1 of the substrate 10 may be about 486 mV, and an average value of the initial surface voltage values measured with respect to each of the second region E2 and the third region E3 of the substrate 10 may be about 488 mV.

Referring to FIGS. 7B, 8B, and 9B, a surface voltage of the substrate 10 may be measured after different types of light having different wavelength ranges are respectively radiated onto the regions E1 to E4 of the substrate 10. As the different types of light having different wavelength ranges are respectively radiated onto the regions E1 to E4 of the substrate 10, average values of surface voltage values measured with respect to each of the regions E1 to E4 of the substrate 10 may be different from each other.

Graph 502a may represent surface voltage values of a first region E1 of the substrate 10 measured after first auxiliary light having a first wavelength range and an electron beam EB onto the first region E1. The first wavelength range may be about 222 nm to 260 nm, and an average value of the surface voltage values of graph 502a may be about 510 mV.

Graph 502b may represent surface voltage values of a second region E2 of the substrate 10 measured after second auxiliary light having a second wavelength range, different from the first wavelength range, and an electron beam EB are radiated onto the second region E2. The second wavelength range may be about 190 nm to 222 nm, and an average value of the surface voltage values of graph 502b may be about 498 mV.

Graph 502c may represent surface voltage values of a third region E3 of the substrate 10 measured after only an electron beam EB is radiated onto the third region E3. An average value of the surface voltage values of graph 502c may be about 491 mV.

Referring to FIGS. 9A, 9B, and 9C, graph 503a may represent a change amount between initial surface voltage values of graph 501a and surface voltage values of graph 502a, graph 503b may represent a change amount between the initial surface voltage values of graph 501b and the surface voltage values of graph 502b, and graph 503c may represent a change amount between initial surface voltage values of graph 501c and surface voltage values of graph 502c.

Referring to graph 503a and graph 503b, when first light having the first wavelength range and an electron beam EB are radiated onto the substrate 10, a change amount between surface voltage values of the substrate 10 may be greater than a change amount between surface voltage values of the substrate 10 when second light having the second wavelength range and the electron beam EB are radiated onto the substrate 10. That is, a target wavelength for the substrate 10 may be the first wavelength range. In an example, when light having the first wavelength range and the electron beam EB are radiated onto the substrate 10, a secondary electron and a backscattered electron emitted from a surface of the substrate 10 may be relatively easily detected.

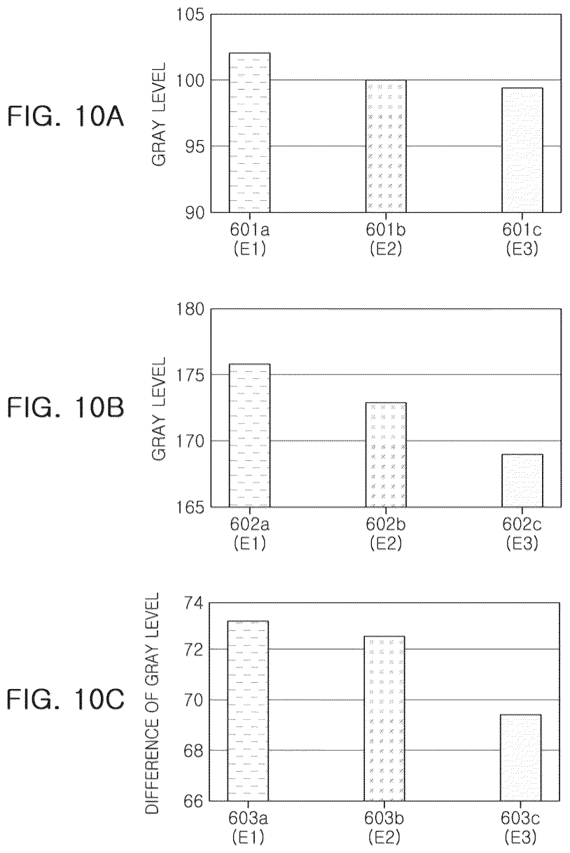

FIG. 10A is a graph illustrating gray levels of respective regions of a substrate according to one or more example embodiments. FIG. 10B is a graph illustrating levels of respective regions of a substrate according to another example embodiment. FIG. 10C is a graph illustrating gray level change amounts of respective regions of a substrate according to one or more example embodiments.

Referring to FIGS. 7A, 8A, and 10A, graph 601a may represent an initial gray level of a first region E1 of a substrate 10, graph 601b may represent an initial gray level of a second region E2 of the substrate 10, and graph 601c may represent an initial gray level of a third region E3 of the substrate 10. An average value of gray levels of the substrate 10 may be about 99.6. An average value of gray levels of the first region E1 of the substrate 10 may be about 102.6, an average value of gray levels of the second region E2 of the substrate 10 may be about 100.2, and an average value of gray levels of the third region E3 of the substrate 10 may be about 96.

Referring to FIGS. 7B, 8B, and 10B, after different types of light having different wavelength ranges are respectively radiated onto regions E1 to E4 of the substrate 10, gray level values may be calculated using an SEM image. As different types of light having different wavelength ranges are respectively radiated onto the regions E1 to E4 of the substrate 10, gray level values respectively calculated with respect to the regions E1 to E4 of the substrate 10 may be different from each other.

Graph 602a may represent a gray level of a first region E1 of the substrate 10 calculated after first auxiliary light having a first wavelength range and an electron beam EB are radiated onto the first region E1. The first wavelength range may be about 222 to 260 nm, and a gray level of graph 602a may be about 175.8.

Graph 602b may represent a gray level of a second region E2 of the substrate 10 calculated after second auxiliary light having a second wavelength range and an electron beam EB are radiated onto the second region E2. The second wavelength range may be about 190 to 222 nm, and a gray level of graph 602b may be about 172.8.

Graph 602c may represent a gray level of a third region E3 of the substrate 10 measured after only an electron beam EB is radiated onto the third region E3. A gray level of graph 602c may be about 165.4.

Referring to FIGS. 10A, 10B, and 10C, graph 603a may represent a change amount between the initial gray level of graph 601a and the gray level of graph 602a, graph 603b may represent a change amount between the initial gray level of graph 601b and the gray level of graph 602b, and graph 603c may represent a change amount between the initial gray level of graph 601c and the gray level of graph 602c.

Referring to graph 603a and graph 603b, when first light having the first wavelength range and an electron beam EB are radiated onto the substrate 10, a change amount between gray levels of the substrate 10 may be greater than a change amount between gray levels of the substrate 10 when second light having the second wavelength range and the electron beam EB are radiated onto the substrate 10. That is, a target wavelength for the substrate 10 may be the first wavelength range. In an example, when light having the first wavelength range and the electron beam EB are radiated onto the substrate 10, a secondary electron and a backscattered electron emitted from a surface of the substrate 10 may be relatively easily detected.

According to example embodiments of the present disclosure, a substrate inspection apparatus and a substrate inspection system according to example embodiments of the present disclosure may include a stage on which a substrate is provided, an electron beam apparatus generating and emitting an electron beam, a lamp module including an optical filter allowing light having a target wavelength, among multi-wavelength light output by a light source, to pass therethrough, and a controller determining a target wavelength and controlling the stage, the electron beam apparatus, and the lamp module, such that light having the electron beam and the light having the target wavelength may be radiated onto the substrate. Accordingly, the target wavelength may vary depending on a conductive pattern disposed on an upper surface of the substrate, and the light having the target wavelength may be radiated onto the substrate to maximize a photoelectric effect, thereby increasing the accuracy of defect detection of the substrate.

While example embodiments have been shown and described above, it will be apparent to those skilled in the art that modifications and variations could be made without departing from the scope of the present disclosure as defined by the appended claims.

What is claimed is:

1. A substrate inspection apparatus comprising:
a stage on which a substrate is to be provided;
an electron beam apparatus configured to generate and emit an electron beam onto the substrate;
a laser assembly configured to generate a first light having a predetermined wavelength;
a lamp assembly comprising a light source configured to generate and emit a multi-wavelength light, and an optical filter configured to pass a second light having a target wavelength, among the multi-wavelength light; and
a processor configured to determine the target wavelength and control the electron beam apparatus, the laser assembly, and the lamp assembly to radiate the first light, the second light, and the electron beam onto the substrate.

2. The substrate inspection apparatus of claim 1, wherein the electron beam apparatus comprises:
an electron gun configured to generate and emit the electron beam;
at least one condensing lens between the stage and the electron gun to pass the electron beam emitted by the electron gun passes; and
a detector configured to detect secondary electrons and backscattered electron emitted from the substrate in response to irradiation by the electron beam.

3. The substrate inspection apparatus of claim 1, wherein the lamp assembly comprises:
a light reflector configured to determine a travelling path of the second light;
an optical modulator between the light reflector and the optical filter, and configured to control an light amount of the second light; and
an optical homogenizer between the light reflector and the optical modulator, and configured to control a density of the second light radiated onto the substrate.

4. The substrate inspection apparatus of claim 3, wherein
the optical modulator comprises a neutral density filter, and
the optical homogenizer comprises a beam homogenizer.

5. The substrate inspection apparatus of claim 1, wherein the optical filter comprises a filter wheel including a plurality of filters.

6. The substrate inspection apparatus of claim 5, wherein the plurality of filters comprises:
a first optical filter configured to pass a first auxiliary light having a first wavelength range, among the multi-wavelength light; and
a second optical filter configured to pass a second auxiliary light having a second wavelength range different from the first wavelength range, among the multi-wavelength light.

7. The substrate inspection apparatus of claim 6, further comprising:
a surface voltage measurement apparatus connected to the processor,
wherein the processor is further configured to:
measure a reference surface voltage of the substrate using the surface voltage measurement assembly;
control the lamp assembly to radiate the first auxiliary light and the electron beam onto a first region of the substrate;
control the lamp assembly to radiate the second auxiliary light and the electron beam onto a second region of the substrate;
measure a first surface voltage of the first region of the substrate a second surface voltage of the second region of the substrate using the surface voltage measurement assembly after radiating the first auxiliary light and the second auxiliary light; and
determine the target wavelength, based on the reference surface voltage, the first surface voltage, and the second surface voltage.

8. The substrate inspection apparatus of claim 7, wherein the processor is further configured to determine the target wavelength, based on a first change amount between the reference surface voltage and the first surface voltage, and a second change amount between the reference surface voltage and the second surface voltage.

9. The substrate inspection apparatus of claim 8, wherein
the first change amount is greater than the second change amount, and
the target wavelength is in the first wavelength range.

10. The substrate inspection apparatus of claim 7, wherein
the first region comprises a plurality of first dies, and
the second region comprises a plurality of second dies, different from the plurality of first dies.

11. The substrate inspection apparatus of claim 7, wherein
the first region comprises a first die, and
the second region comprises a second die, different from the first die.

12. The substrate inspection apparatus of claim 6, wherein the processor is further configured to:
calculate a reference gray level of the substrate;
control the lamp assembly to radiate the first auxiliary light and the electron beam onto a first region of the substrate;
control the lamp assembly to radiate the second auxiliary light and the electron beam onto a second region of the substrate;
calculate a first gray level of the first region of the substrate and a second gray level of the second region of the substrate after radiating the first auxiliary light and the second auxiliary light; and
determine the target wavelength, based on the reference gray level, the first gray level, and the second gray level.

13. A substrate inspection system comprising:
a stage on which a substrate is to be provided;
an electron beam apparatus configured to radiate an electron beam onto the substrate;
a lamp assembly comprising a light source configured to generate and emit a multi-wavelength light, and an optical filter configured to pass a first light having a target wavelength, among the multi-wavelength light; and
a processor configured to:
control the lamp assembly to radiate a first auxiliary light having a first wavelength range, among the multi-wavelength light, onto a first region of the substrate;
control the lamp assembly to radiate a second auxiliary light having a second wavelength range different from the first wavelength range, among the multi-wavelength light, onto a second region of the substrate; and
determine the target wavelength, based on at least one of surface voltages and gray levels for the first region of the substrate and the second region of the substrate.

14. The substrate inspection system of claim 13, wherein the target wavelength varies depending on a material of a conductive pattern disposed on the substrate.

15. The substrate inspection system of claim 13, wherein the processor is further configured to:
control the electron beam apparatus and the lamp assembly to radiate the electron beam and the first light onto the substrate, respectively, based on determination of the target wavelength, and
control the electron beam apparatus to detect at least one of secondary electrons or backscattered electrons emitted from the substrate.

16. The substrate inspection system of claim 15, wherein the processor is further configured to:
generate a scanning electron microscope (SEM) image of the substrate using the detected at least one of the secondary electrons and the backscattered electrons; and
determine, based on the SEM image, whether defects are present in the substrate.

17. The substrate inspection system of claim 13, wherein the electron beam apparatus comprises a scanning electron microscope (SEM).

18. The substrate inspection system of claim 13, wherein the processor is further configured to control the optical filter of the lamp assembly to sequentially radiate the first auxiliary light onto the first region of the substrate and the second auxiliary light radiated onto the second region of the substrate.

19. A substrate inspection apparatus comprising:
a stage on which a substrate is to be provided;
an electron beam apparatus configured to radiate an electron beam onto the substrate;
a laser assembly configured to radiate a first light having a predetermined wavelength onto the substrate;
a lamp assembly comprising a light source configured to generate and emit a multi-wavelength light, and an optical filter configured to pass a second light having a target wavelength, among the multi-wavelength light; and
a processor configured to determine the target wavelength, based on a material of a conductive pattern on the substrate, and control the electron beam apparatus, the laser assembly, and the lamp assembly to radiate the first light, the second light, and the electron beam onto the substrate.

20. The substrate inspection apparatus of claim 19, wherein the electron beam apparatus is on an upper portion of a region between the laser assembly and the lamp assembly.
